(19) United States
(12) Patent Application Publication
(10) Pub. No.: US 2026/0171125 A1
(43) Pub. Date: Jun. 18, 2026

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Jongseon AHN, Suwon-si (KR); Donghwan KIM, Suwon-si (KR); Sewoon LEE, Suwon-si (KR); Joohang LEE, Suwon-si (KR)

(73) Assignee: Samsung Electronics Co., Ltd., Suwon-si (KR)

(21) Appl. No.: 19/302,449

(22) Filed: Aug. 18, 2025

(30) Foreign Application Priority Data
Dec. 17, 2024 (KR) 10-2024-0188925

(51) Int. Cl. G11C 5/06; H01L 23/00; H01L 25/18; H10B 41/10; H10B 41/27; H10B 41/35; H10B 41/41; H10B 43/10; H10B 43/27; H10B 43/35; H10B 43/40; H10B 80/00; H10D 80/30

(52) U.S. Cl. CPC G11C 5/063; H10B 41/10; H10B 41/27; H10B 41/35; H10B 41/41; H10B 43/10; H10B 43/27; H10B 43/35; H10B 43/40; H10B 80/00; H10D 80/30; H10W 90/00; H10W 90/792

(57) ABSTRACT

A semiconductor device may include a first semiconductor structure including a lower bonding structure; and a second semiconductor structure including an upper bonding structure bonded to the lower bonding structure, the second semiconductor structure including a conductive layer; memory gate electrodes; first channel structures penetrating through the memory gate electrodes; a first horizontal insulating layer below the memory gate electrodes; a selection gate conductive layer including selection gate electrode regions overlapping the first channel structures and dummy regions; insulating regions penetrating through the selection gate conductive layer to separate the selection gate electrode regions and the dummy regions; second channel structures penetrating through the selection gate electrode regions; address studs below the dummy regions; channel studs below the second channel structures; and upper interconnection structures below the selection gate conductive layer, connected to the channel studs, and spaced apart from the address studs.

### CROSS-REFERENCE TO RELATED APPLICATION(S)

This application claims benefit of priority to Korean Patent Application No. 10-2024-0188925 filed on Dec. 17, 2024, in the Korean Intellectual Property Office, the disclosure of which is incorporated herein by reference in its entirety.

### BACKGROUND

The present disclosure relates to semiconductor devices and data storage systems including the same.

In data storage systems which use data storage, semiconductor devices capable of storing large amounts of data are beneficial. Accordingly, methods for increasing the data storage capacity of semiconductor devices have been researched. For example, in some methods for increasing the data storage capacity of semiconductor devices, a semiconductor device including memory cells arranged three-dimensionally, instead of two-dimensionally, has been proposed.

### SUMMARY

Aspects of the present disclosure are to provide semiconductor devices capable of reliable quality inspection.

Aspects of the present disclosure are to provide data storage systems including a semiconductor device capable of reliable operation error inspection.

In example embodiments, provided is a semiconductor device including a first semiconductor structure including a first substrate, circuit elements on the first substrate, a lower interconnection structure electrically connected to the circuit elements, and a lower bonding structure connected to the lower interconnection structure; and a second semiconductor structure including an upper bonding structure bonded to the lower bonding structure on the first semiconductor structure, the second semiconductor structure including a conductive layer; memory gate electrodes spaced apart from each other and stacked in a first direction below the conductive layer, the first direction perpendicular to an upper surface of the conductive layer; first channel structures including a channel layer and penetrating through the memory gate electrodes in the first direction; a first horizontal insulating layer below the memory gate electrodes and the first channel structures; a selection gate conductive layer below the first horizontal insulating layer and including selection gate electrode regions overlapping the first channel structures in the first direction and dummy regions; insulating regions extending in a second direction penetrating through the selection gate conductive layer, and spaced apart from each other in a third direction to separate the selection gate electrode regions and the dummy regions, the second direction being perpendicular to the first direction, and the third direction being perpendicular to the second direction; second channel structures penetrating through the selection gate electrode regions and electrically connected to the first channel structures, respectively; address studs spaced apart from each other by a first separation distance in the second direction below the dummy regions; channel studs below the second channel structures; and upper interconnection structures below the selection gate conductive layer, connected to the channel studs, and spaced apart from the address studs.

In example embodiments, provided is a semiconductor device including a first semiconductor structure including a first substrate, circuit elements on the first substrate, a lower interconnection structure electrically connected to the circuit elements, and a lower bonding structure connected to the lower interconnection structure; and a second semiconductor structure including an upper bonding structure bonded to the lower bonding structure on the first semiconductor structure, a conductive layer; gate electrodes including memory gate electrodes and a selection gate electrode spaced apart from each other and stacked in a first direction below the conductive layer, the first direction perpendicular to an upper surface of the conductive layer; channel structures including a channel layer, the channel structures penetrating through the gate electrodes in the first direction; insulating regions extending in a second direction penetrating through the selection gate electrode, and spaced apart from each other in a third direction to separate the selection gate electrode into selection gate electrode regions and dummy regions, the second direction being perpendicular to the first direction, and the third direction being perpendicular to the second direction; address studs spaced apart from each other by a first separation distance in the second direction below at least one dummy region, among the dummy regions; and channel studs below the channel structures.

In example embodiments, provided is a data storage system including a semiconductor storage device including a first semiconductor structure including a substrate and circuit elements on the substrate; a second semiconductor structure including gate electrodes including memory gate electrodes and selection gate electrodes stacked in a first direction and channel structures penetrating through the gate electrodes; and an input/output pad electrically connected to the circuit elements; and a controller electrically connected to the semiconductor storage device through the input/output pad and configured to control the semiconductor storage device, the first semiconductor structure further including a lower interconnection structure electrically connected to the circuit elements; and a lower bonding structure connected to the lower interconnection structure, and the second semiconductor structure including an upper interconnection structure below the gate electrodes; an upper bonding structure connected to the upper interconnection structure and bonded to the lower bonding structure; insulating regions extending in a second direction, perpendicular to the first direction, penetrating through the selection gate electrode, and spaced apart from each other in a third direction to separate the selection gate electrode into selection gate electrode regions and dummy regions, the third direction being perpendicular to the second direction; address studs spaced apart from each other by a first separation distance in the second direction below at least one dummy region, among the dummy regions; and channel studs below the channel structures, the upper interconnection structure connected to the channel studs and spaced apart from the address studs.

In example embodiments, provided is a method of manufacturing a semiconductor device including forming a peripherical circuit region including circuit elements, a lower interconnection structure, a lower bonding structure, and a lower capping layer, forming a cell region including forming a mold structing including sacrificial insulating layers alternatively stacked with interlayer insulating layers on a base substrate, and sacrificial vertical structures penetrating the sacrificial insulating layers alternatively stacked with the interlayer insulating layers, forming first channel structures and second channel structures by removing the sacrificial vertical structures to define channel holes and filling the channel holes with an information storage structure, a channel layer, a buried insulating layer, and a channel pad, forming gate electrodes by selectively removing the sacrificial insulating layers to define gate spaces and filling the gate spaces, forming upper channel structures on an upper on the first and second channel structures, forming a horizontal insulating layer over upper surfaces of the upper channel structures, forming a first capping insulating layer on the horizontal insulating layer, forming first and second stud holes, the first stud holes defined by the first capping insulating layer, the second stud holes defined by the first capping insulating layer and the horizontal insulating layer, forming channel studs in the first stud holes and address studs in the second stud holes, and forming upper interconnection structures on the channel studs and the address studs, and bonding the peripheral circuit structure and the cell structure together.

In example embodiments, the method of manufacturing the semiconductor device may further include the address studs being spaced apart from each other by a first separation distance below at least one dummy region; and the upper interconnection structure is connected to the channel studs and spaced apart from the address studs

In a structure in which two or more semiconductor structures are bonded, when performing an operation error inspection, the bonded structure is recut to capture an image, and a position of the error point may be identified therethrough. In this case, in a cell structure captured from the cut surface, repetitive circuit patterns, such as bit lines and studs of a channel structure, are imaged, which may make it difficult to identify a position of error points. Accordingly, address studs for specifying the position of the error point may be disposed according to a rule, thereby calculating the position of the error point.

The address studs may be disposed on a dummy region of an upper gate electrode, and may thus be disposed in a position clearly distinguished from the studs on the channel structure.

Accordingly, semiconductor devices having improved reliability and data storage systems including the same may be provided through an error inspection with improved reliability.

Advantages and effects of the present application are not limited to the foregoing content and may be more easily understood in the process of describing some specific example embodiments of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic plan view of a semiconductor device according to example embodiments;

FIG. 2 is a partially enlarged view of a semiconductor device according to example embodiments;

FIG. 3 is a schematic cross-sectional view of a semiconductor device according to example embodiments;

FIGS. 4A and 4B are enlarged cross-sectional views of some regions of FIG. 3;

FIGS. 5 to 7 are enlarged views of a semiconductor device according to example embodiments;

FIG. 8 is a plan view of a semiconductor device according to some example embodiments;

FIGS. 9A to 9I are schematic cross-sectional views illustrating a method of manufacturing a semiconductor device according to example embodiments;

FIG. 10 is a view schematically illustrating a data storage system including a semiconductor device according to example embodiments; and

FIG. 11 is a perspective view schematically illustrating a data storage system including a semiconductor device according to some example embodiments.

### DETAILED DESCRIPTION

Hereinafter, example embodiments of the present disclosure will be described with reference to the accompanying drawings. Hereinafter, it may be understood that the expressions such as “on,” “above,” “upper,” “below,” “beneath,” “lower,” and “side” merely indicated based on drawings, except that they are indicated by drawings and referred to separately.

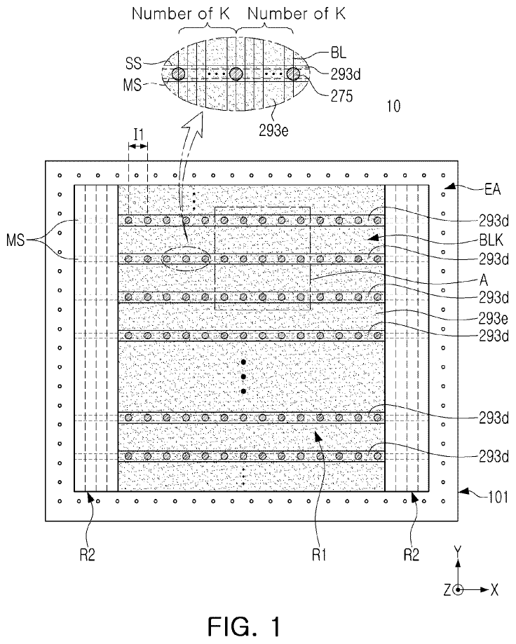

Hereinafter, a semiconductor device according to example embodiments will be described with reference to FIGS. 1 to 4B.

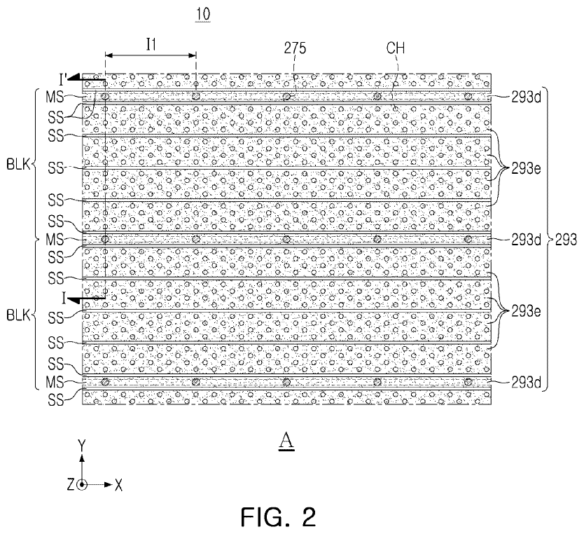

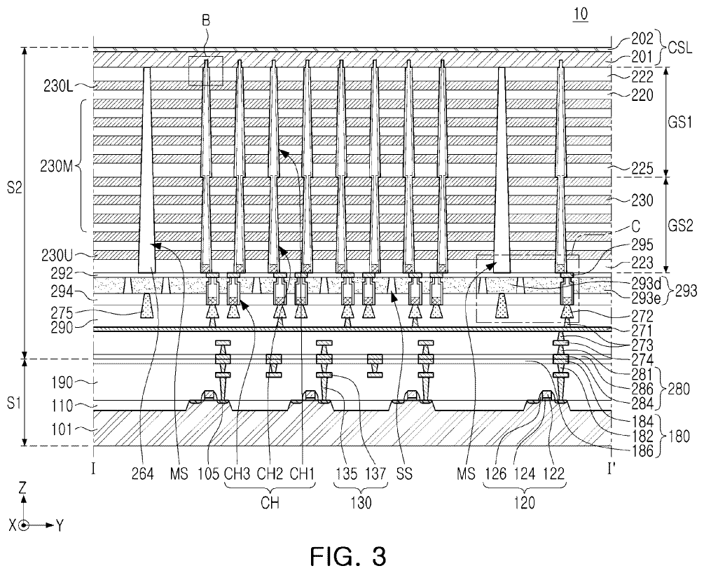

FIG. 1 is a schematic plan view of a semiconductor device according to example embodiments, FIG. 2 is an enlarged plan view of region ‘A’ of FIG. 1, and FIG. 3 is a schematic cross-sectional view of a semiconductor device according to example embodiments. FIG. 3 is a cross-sectional view taken along line I-I′ of FIG. 2. The plan view of FIG. 1 is a cross-sectional view of a second semiconductor structure taken along an upper interconnection structure of the second semiconductor structure in the cross-sectional view of FIG. 3.

A semiconductor device 10 may include a first semiconductor structure S1 and a second semiconductor structure S2, and the first semiconductor structure S1 may be stacked in a Z-direction, which is a vertical direction with respect to the second semiconductor structure S2. Specifically, the first semiconductor structure S1 may be disposed below the second semiconductor structure S2 in the Z-direction. In example embodiments, on the contrary, the second semiconductor structure S2 may be disposed below the first semiconductor structure S1.

In example embodiments, the semiconductor device 10 may include a peripheral circuit structure PERI (see FIG. 3), which is a first semiconductor structure S1 in which a peripheral circuit region is formed on a first substrate 101, and a memory cell structure CELL (see FIG. 3), which is a second semiconductor structure S2 including a common source line CSL.

The first semiconductor structure S1 may form a peripheral circuit by forming transistors and metal patterns for wiring the transistors on the first substrate 101. The second semiconductor structure S2 of the semiconductor device 10 may include memory blocks BLK which are a set of a plurality of channel structures CH.

The semiconductor device 10 may include a first region R1 in an X-direction and a second region R2 on both sides of the first region R1.

The first region R1 may be a memory cell region in which memory cells are disposed and may be a region in which channel structures CH are disposed, and the second region R2 may correspond to a region for electrically connecting the memory cells to peripheral circuit structures PERI, and for this purpose, the second region R2 may be regions in which gate electrodes 230 extend by different lengths, but the present disclosure is not limited thereto.

Referring to FIG. 1, an edge region EA may be disposed on each side. The edge region EA may be disposed on the outside of the second region R2, and in an upper portion and a lower portion of the first region R1, and may be a region in which a mold structure remains. The edge region EA may be defined as a region in which a pad region connected from the outside is disposed, or external contact vias connected to the pad region are disposed, or various through-vias connected to the first semiconductor structure S1 are disposed. The semiconductor device 10 is illustrated as having an edge region EA disposed on each side to have a frame shape, but the present disclosure is not limited thereto.

The semiconductor device 10 may have separation regions MS extending in the X-direction within the first region R1 and the second region R2. The separation regions MS may be spaced apart from each other in a Y-direction, and may be defined as one memory block BLK between adjacent separation regions MS. The memory block BLK may be utilized as an operation unit of the channel structures CH, and a signal application unit, but the present disclosure is not limited thereto.

In the first region R1, an upper gate conductive layer 293 may be disposed to cover the channel structures CH. The upper gate conductive layer 293 may cover an entire first region R1, and may be penetrated by upper channel structures CH3 among the channel structures CH, respectively.

The upper gate conductive layer 293 may include upper gate electrode regions 293e penetrated by the upper channel structures CH3 to function as gate electrodes, and upper dummy regions 293d overlapping the separation regions MS and electrically/physically separated from the upper gate electrode regions 293e.

On an X-Y plane, the upper gate conductive layer 293 may be separated by upper insulating regions SS to form the upper gate electrode regions 293e and the upper dummy regions 293d.

At least three upper insulating regions SS may be disposed between two adjacent separation regions MS in the Y-direction. The upper insulating regions SS may extend continuously in the X-direction, and may penetrate through the upper gate conductive layer 293. The upper insulating regions SS may separate the upper gate conductive layer 293 to form the upper gate electrode regions 293e between the two separation regions MS.

The upper gate electrode regions 293e separated from each other in the Y-direction may be electrically connected to each other by different string selection plugs to receive a string selection signal.

Some of the upper insulating regions SS may define the upper dummy regions 293d extending in the X-direction on both sides of the separation region MS and physically/electrically separated from the upper gate electrode regions 293e. Accordingly, the upper dummy region 293d may be in contact with the upper insulating regions SS on both sides in the Y-direction, and the separation regions MS may be disposed on an upper portion thereof.

The upper dummy regions 293d may be assigned to each of the separation regions MS, and may be electrically/physically completely insulated from the adjacent upper gate electrode regions 293e and may include a conductive material but may maintain a floating state. Each of the upper dummy regions 293d may have a smaller area than each of the upper gate electrode regions 293e, but the present disclosure not limited thereto.

Address studs 275 may be disposed by corresponding to each of the upper dummy regions 293d. The address studs 275 may be disposed in each upper dummy region 293d, but the present disclosure not limited thereto.

The address studs 275 disposed on the upper dummy regions 293d may be arranged regularly in the X-direction by a separation distance I1 to form one row.

The address studs 275 of each row may be disposed in the same number. The address studs 275 of a first row may be spaced apart from each other by the same separation distance I1, for example, a distance equal to the sum of the pitches (multiples of the pitches) of a predetermined (or, alternatively, desired, determined, or selected) number (k) of bit lines BL. In some example embodiments, k may be 50, 100, or the like.

The address studs 275 spaced apart from each other by the same separation distance I1 may be repeatedly disposed on one upper dummy region 293d. Additionally, the address studs 275 may be arranged to have the same separation distance I1 for other upper dummy regions 293d. The address studs 275 may be arranged to be aligned with each other in the Y-direction.

Accordingly, during an error inspection, an arrangement of the address studs 275 and a position of the upper dummy region 293d in which the address studs 275 are disposed, may be confirmed, thereby confirming a position in which errors have occurred, that is, which memory block BLK a position of an error point is in the Y-direction or which bit line BL the position of an error point is in the X-direction.

Hereinafter, with reference to FIGS. 2 to 4B, some example embodiments of the present disclosure will be described in more detail.

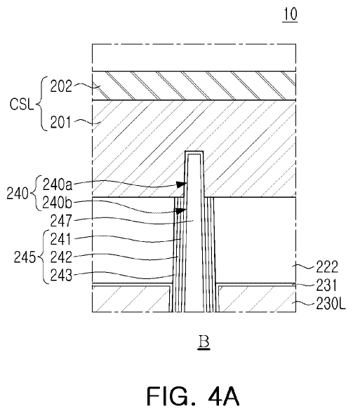

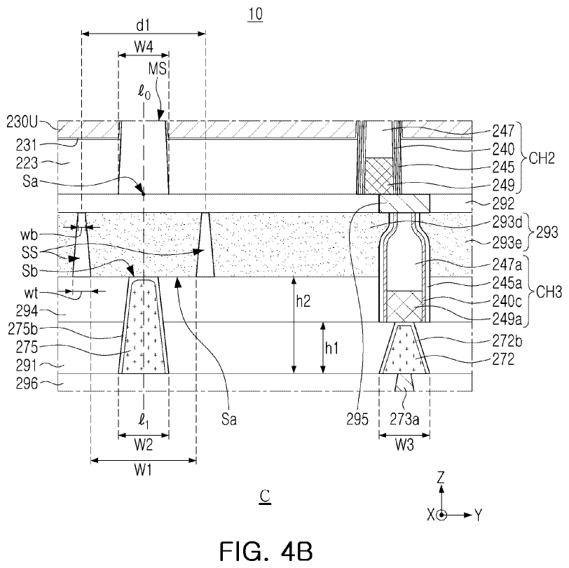

FIG. 2 is an enlarged view of portion ‘A’ of FIG. 1, and FIG. 3 illustrates a cross-section taken along cutting line I-I′ of FIG. 2. FIGS. 4A and 4B are enlarged views of portion ‘B’ and portion ‘C’ of FIG. 3, respectively.

Referring to FIGS. 2 to 4B, the semiconductor device 10 may include a first semiconductor structure S1 defined as the peripheral circuit structure PERI and a second semiconductor structure S2 defined as the memory cell structure CELL on the first semiconductor structure S1. The first semiconductor structure S1 and the second semiconductor structure S2 may be bonded to each other through bonding structures 180 and 280.

The first semiconductor structure S1 may include a first substrate 101, circuit elements 120 on the first substrate 101, a lower interconnection structure 130, a lower bonding structure 180, and a lower capping layer 190.

The first substrate 101 may include a semiconductor material, such as a group IV semiconductor, a group III-V compound semiconductor, or a group II-VI compound semiconductor. The first substrate 101 may be provided as a bulk wafer or an epitaxial layer. An active region may be defined by element isolation layers 110 in the first substrate 101. Source/drain regions 105 including impurities may be disposed in a portion of the active region.

The circuit elements 120 may include a transistor. Each of the circuit elements 120 may include a circuit gate dielectric layer 122, a circuit gate electrode 124, a spacer layer 126, and a source/drain region 105. The source/drain regions 105 including impurities may be disposed in the first substrate 101 on both sides of the circuit gate electrode 124. The spacer layers 126 may be disposed on both sides of the circuit gate electrode 124. The circuit gate dielectric layer 122 may include silicon oxide, silicon nitride, or a high-κ material. The circuit gate electrode 124 may include at least one of doped silicon, titanium nitride (TiN), tantalum nitride (TaN), tungsten nitride (WN), titanium silicon nitride (TiSiN), tantalum silicon nitride (TaSiN), tungsten silicon nitride (WSiN), tungsten (W), copper (Cu), aluminum (Al), molybdenum (Mo), or ruthenium (Ru). For example, the circuit gate electrode 124 may include a doped polycrystalline silicon layer. According to some example embodiments, the circuit gate electrode 124 may be formed of two or more multilayers.

The lower interconnection structure 130 may be electrically connected to the circuit gate electrodes 124 of the circuit elements 120 and the source/drain regions 105. The lower interconnection structure 130 may include lower contact plugs 135 and lower interconnection lines 137 in which at least one region has a line shape. Some of the lower contact plugs 135 may be connected to the source/drain regions 105, and, although not illustrated, other of the lower contact plugs 135 may be connected to the circuit gate electrodes 124. The lower contact plugs 135 may electrically connect the lower interconnection lines 137 disposed on different levels from the upper surface of the first substrate 101 to each other. The lower interconnection structure 130 may include a conductive material, and may include, for example, tungsten (W), copper (Cu), and/or aluminum (Al), and each of the components may further include a diffusion barrier layer including at least one of titanium (Ti), titanium nitride (TiN), tantalum (Ta), tantalum nitride (TaN), and tungsten nitride (WN). According to example embodiments, the number of layers of the lower contact plugs 135 and the lower interconnection lines 137 included in the lower interconnection structure 130 and an arrangement shape thereof may be variously changed.

The lower bonding structure 180 may be connected to the lower interconnection structure 130. The lower bonding structure 180 may include a lower bonding via 182, a lower bonding pad 184, and a lower bonding insulating layer 186. The lower bonding via 182 may be connected to the lower interconnection structure 130. The lower bonding pad 184 may be connected to the lower bonding via 182. The lower bonding via 182 and the lower bonding pad 184 may include a conductive material, and may include, for example, tungsten (W), copper (Cu), and/or aluminum (Al), and each of the components may further include a diffusion barrier layer. The lower bonding insulating layer 186 may also function as a diffusion barrier layer of the lower bonding pad 184, and may include at least one of silicon oxide, silicon nitride, silicon oxynitride, or silicon oxycarbide. The lower bonding insulating layer 186 may have a thickness thinner than a thickness of the lower bonding pad 184, but the present disclosure is not limited thereto. The lower bonding structure 180 may be in direct contact with and bonded or connected to the upper bonding structure 280 by hybrid bonding. For example, the lower bonding pad 184 may be in contact with and bonded to an upper bonding pad 284 by copper-to-copper bonding, and the lower bonding insulating layer 186 may be in contact with and bonded to an upper bonding insulating layer 286 by dielectric-to-dielectric bonding. The lower bonding structure 180 may provide an electrical connection path between the peripheral circuit structure PERI S1 and the memory cell structure CELL S2 together with the upper bonding structure 280.

The lower capping layer 190 may be disposed on the first substrate 101 to cover the circuit elements 120 and the lower interconnection structure 130. The lower capping layer 190 may include a plurality of insulating layers. The lower capping layer 190 may include an insulating material, such as silicon oxide, silicon nitride, silicon oxynitride, or silicon oxycarbide.

The second semiconductor structure S2, which is a memory cell structure, may include a first conductive layer 201 in the first region R1, which is a memory cell region, a second conductive layer 202 on an upper surface of the first conductive layer 201, gate electrodes 230 stacked on a lower surface of the first conductive layer 201 in the first region R1 and the second region R2, interlayer insulating layers 220 alternately stacked with the gate electrodes 230, channel structures CH disposed to penetrate through the gate electrodes 230, separation regions MS extending in one direction by penetrating through the gate electrodes 230, and upper insulating regions SS penetrating through the upper gate conductive layer 293. The second semiconductor structure S2 may include an edge region EA surrounding the first region R1 and the second region R2. The second semiconductor structure S2 may further include an upper capping layer 290 covering the gate electrodes 230 and the upper gate conductive layer 293. The gate electrodes 230 may be vertically spaced apart from each other and stacked on the lower surface of the first conductive layer 201 to form a stack structures GS1 and GS2 together with the interlayer insulating layers 220.

The second semiconductor structure S2 may include channel studs 272 for electrical connection with the first semiconductor structure S1, upper interconnection structures 271, 273, and 274 below the stack structures GS1 and GS2, and an upper bonding structure 280 connected to the upper interconnection structures 271, 273, and 274. The second semiconductor structure S2 may include address studs 275 disposed on the same or substantially the same level as the channel studs 272 and disposed on the upper dummy region 293d of the upper gate conductive layer 293.

The second semiconductor structure S2 may further include contact plugs in the second region R2 and external contact vias in the edge region EA.

The first region R1 may be a region in which the gate electrodes 230 are spaced apart from each other and stacked in the vertical direction, for example, the Z-direction, as illustrated in FIG. 2, and channel structures CH are disposed. The second region R2 may be disposed on both sides of the first region R1 in the X-direction, as illustrated in FIG. 1, and may be a region in which contact plugs connected to the gate electrodes 230, respectively, to electrically connect the memory cells to the first semiconductor structure S1, are disposed.

The stack structures GS1 and GS2 may include a plurality of stack structures GS1 and GS2 vertically stacked. In FIG. 3, lower and upper stack structures GS1 and GS2 are illustrated as being included, but the present disclosure is not limited thereto, and stack structures GS1 and GS2 may include three to five-stage stack structures GS1 to GSd (for example, d is 3 to 5). However, according to example embodiments, the stack structures GS1 to GSd may be formed as a single stack structure.

The gate electrodes 230 may include at least one lower gate electrode 230L included in a gate of a ground selection transistor, memory gate electrodes 230M included in a plurality of memory cells, and upper gate electrodes 230U. Here, the lower gate electrode 230L and the upper gate electrodes 230U may be referred to as “lower” and “upper” based on a direction during the manufacturing process. The number of memory gate electrodes 230M included in the memory cells may be determined according to the capacity of the semiconductor device 10. According to some example embodiments, the number of upper and lower gate electrodes 230U and 230L may be one to two or more, respectively, and the upper and lower gate electrodes 230U and 230L may have a structure identical to or different from the memory gate electrodes 230M. In some example embodiments, erase gate electrodes may be further disposed below the upper gate electrodes 230U. Additionally, some of the gate electrodes 230, for example, the memory gate electrodes 230M adjacent to the upper or lower gate electrodes 230U and 230L, may be dummy gate electrodes, but the present disclosure is not limited thereto.

The gate electrodes 230 may be disposed to be separated from each other in the Y-direction by separation regions MS extending continuously within the first region R1 and the second region R2. The gate electrodes 230 between a pair of separation regions MS may form one memory block BLK. Some of the gate electrodes 230, for example, the memory gate electrodes 230M, may form one layer each within one memory block BLK.

The gate electrodes 230 may be vertically spaced apart from each other and stacked within the first region R1 and the second region R2, and may extend from the first region R1 to the second region R2 by different lengths, thereby forming a portion of the second region R2, for example, a staircase-shaped step structure in the second region R2. By the step structure, each of the gate electrodes 230 may have regions in which the lower gate electrode 230 extends to be longer than the upper gate electrode 230 and upper surfaces thereof are exposed upwardly from the interlayer insulating layers 220 and other gate electrodes 230, and these regions may be referred to as pad regions. In each gate electrode 230, the pad region may be a region including an end of the gate electrode 230 in the X-direction. The gate electrodes 230 may be respectively connected to the contact plugs in the pad regions.

The gate electrodes 230 may include a metallic material, such as tungsten (W). According to some example embodiments, the gate electrodes 230 may include polycrystalline silicon or a metal silicide material. According to example embodiments, the gate electrodes 230 may further include a diffusion barrier layer 231, and for example, the diffusion barrier layer 231 may include tungsten nitride (WN), tantalum nitride (TaN), titanium nitride (TiN), or combinations thereof.

The interlayer insulating layers 220 may be disposed between the gate electrodes 230 and may thus be included in the stack structures GS1 and GS2. Similarly to the gate electrodes 230, the interlayer insulating layers 220, may be spaced apart from each other in a direction, perpendicular to the lower surface of the first conductive layer 201, and may extend in the X-direction. The interlayer insulating layers 220 may extend to the edge region EA and may be disposed between sacrificial insulating layers 218, thus forming a mold structure. The interlayer insulating layers 220 may include an insulating material such as silicon oxide or silicon nitride.

In example embodiments, thicknesses of the interlayer insulating layers 220 may not all be the same. For example, an uppermost interlayer insulating layer 223, a lowermost interlayer insulating layer 222, and an intermediate interlayer insulating layer 225, among the interlayer insulating layers 220 may have a greater thickness than the other interlayer insulating layers 220, but the present disclosure is not limited thereto. The intermediate interlayer insulating layer 225 may be defined as interlayer insulating layers between the stack structures GS1 and GS2.

As described above, the separation regions MS may be disposed to extend in the X-direction by penetrating through the gate electrodes 230. The separation regions MS may be spaced apart from each other in the Y-direction and may be disposed to be parallel to each other. The separation regions MS may be connected to the upper capping layer 290 by penetrating through the entire laminated gate electrodes 230. The separation regions MS may extend as one in the X-direction, but may extend intermittently in some regions or may be disposed only in some regions.

A separation insulating layer 264 may be disposed in the separation regions MS. The separation insulating layer 264 may have a shape in which a width thereof increases toward the first substrate 101 due to a high aspect ratio, but the present disclosure is not limited thereto. The separation insulating layer 264 may not extend to the edge region EA.

As illustrated in FIG. 2, the separation regions MS may be formed to have flat side surfaces, but the present disclosure is not limited thereto. The separation regions MS may have inclined side surfaces by increasing a width thereof from an upper portion to a lower portion thereof. In this case, unlike the channel structures CH, the side surfaces may be continuously inclined without a bent portion. A lower width W4 of the separation regions MS, e.g., a lower width W4 in the Y-direction, may be greater than a lower width of a second channel structure CH2 of the channel structure CH, but the present disclosure is not limited thereto.

The channel structures CH may be spaced apart from each other by forming rows and columns on the lower surface of the first conductive layer 201 of the first region R1. The channel structures CH may be disposed in a zigzag shape in one direction in the X-Y plane. The channel structures CH may penetrate through the gate electrodes 230, may extend in a vertical direction, perpendicular to the lower surface of the first conductive layer 201, for example, in the Z-direction, and may have a pillar shape, and may have an inclined side surface in which a width thereof becomes narrower as the channel structures CH approach the first conductive layer 201 depending on the aspect ratio.

Each of the channel structures CH is a lower channel structure penetrating through the gate electrodes 230, may include a first channel structure CH1 and a second channel structure CH2, and may include an upper channel structure CH3 penetrating through the upper gate electrode region 293e. The lower channel structure may have a form in which the first channel structure CH1 and the second channel structure CH2 penetrating through the lower stack structure GS1 and the upper stack structure GS2, respectively, are connected, and may have a bending portion due to a difference or change in width in the connection region.

As illustrated in the enlarged view of FIG. 4A, the first and second channel structures CH1 and CH2 may include a first portion within the stack structures GS1 and GS2 and a second portion protruding above the stack structures GS1 and GS2.

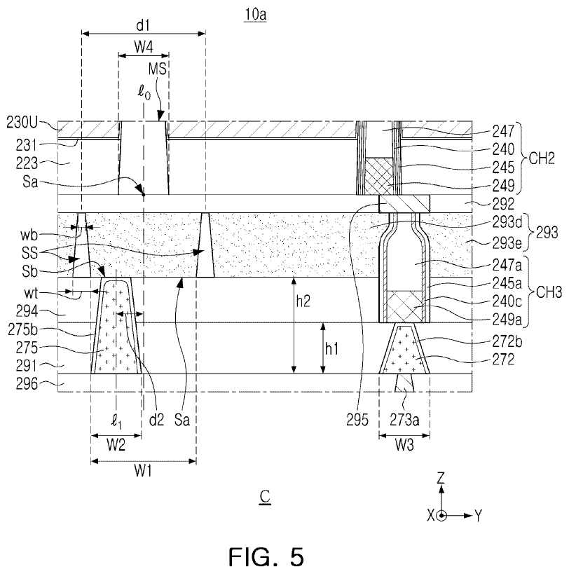

A channel layer 240 may be entirely disposed on the first portion and the second portion of the first and second channel structures CH1 and CH2, and may be disposed up to an upper end of the second portion. The channel layer 240 may be disposed on the second portion of the first and second channel structures CH1 and CH2, and the channel layer 240 may include a protrusion 240a protruding and exposed above the stack structures GS1 and GS2 and a non-protrusion 240b disposed on the first portion of the first and second channel structures CH1 and CH2. The channel layer 240 may be formed in an annular shape in which a side surface thereof surrounds a buried insulation layer 247 inside, but may also have a columnar shape such as a cylindrical or angular column without the buried insulation layer 247, depending on some example embodiments. The protrusion 240a of the channel layer 240 may be covered with the first conductive layer 201 and may be in direct contact with the first conductive layer 201. The protrusion 240a may be formed to have a gentle slope with the non-protrusion 240b so that the annular shape is maintained, as illustrated in FIG. 5A. The channel layer 240 may include a semiconductor material such as polycrystalline silicon or single-crystal silicon, and the semiconductor material may be an undoped material or a material including P-type or N-type impurities.

In the first and second channel structures CH1 and CH2, channel pads 249 may be disposed in a lower portion of the channel layer 240. The channel pads 249 may be disposed to cover a lower surface of the buried insulating layer 247 and may be electrically connected to the channel layer 240. The channel pads 249 may include, for example, doped polycrystalline silicon.

An information storage structure 245 may be disposed between the gate electrodes 230 and the channel layer 240. The information storage structure 245 may include a tunneling layer 241, a charge storage layer 242, and a blocking layer 243 sequentially stacked from the channel layer 240. The tunneling layer 241 may tunnel charges into the charge storage layer 242, and may include, for example, silicon oxide (SiO₂), silicon nitride (Si₃N₄), silicon oxynitride (SiON), or combinations thereof. The charge storage layer 242 may be a charge trap layer or a floating gate conductive layer. The blocking layer 243 may include silicon oxide (SiO₂), silicon nitride (Si₃N₄), silicon oxynitride (SiON), a high-κ dielectric material, or combinations thereof. According to example embodiments, at least a portion of the information storage structure 245 may form a channel dielectric layer extending in a horizontal direction along the gate electrodes 230.

The information storage structure 245 may be removed from upper portions of the stack structures GS1 and GS2 so that the protrusion 240a of the channel layer 240 is exposed to the outside in the second portion. Accordingly, an upper end of the information storage structure 245 may be in contact with the first conductive layer 201, and may be arranged so that a side surface of the information storage structure 245 in the first portion surrounds the non-protrusion 240b of the channel layer 240. For example, the upper end of the information storage structure 245 and the upper end of the lowermost interlayer insulating layer 222 may be coplanar or substantially coplanar.

The channel layer 240, the information storage structure 245 and the buried insulating layer 247 may be connected to each other between the second channel structure CH2 and the first channel structure CH1. As described above, a relatively thick intermediate interlayer insulating layer 225 may be disposed between the second channel structure CH2 and the first channel structure CH1.

Each channel structure CH may include an upper channel structure CH3 connected to the channel pad 249 of the second channel structure CH2.

The upper channel structures CH3 may extend in the Z-direction by penetrating through the upper gate electrode region 293e, and may be connected to the first and second channel structures CH1 and CH2, which are lower channel structures, respectively. The upper channel structures CH3 may be respectively disposed on the first and second channel structures CH1 and CH2, and may be disposed by being shifted in the horizontal direction from the first and second channel structures CH1 and CH2, but the present disclosure is not limited thereto.

As illustrated in FIGS. 3 and 4B, each of the upper channel structures CH3 may include an upper channel layer 240c, an upper gate dielectric layer 245a, an upper channel buried insulating layer 247a, and an upper channel pad 249a, disposed within an upper channel hole. The upper channel layer 240c may be formed in an annular shape surrounding the upper channel buried insulating layer 247a inside. The upper channel layer 240c may be connected to a connection pad 295 in an upper portion, and may be electrically connected to the channel layer 240 of the first and second channel structures CH1 and CH2 in an upper portion thereof through the connection pad 295.

The descriptions of the lower channel layer 240, the information storage structure 245, the channel buried insulating layer 247 and the channel pad layer 249 described above may be equally applied to the description of the materials of the upper channel layer 240c, the upper gate dielectric layer 245a, the upper channel buried insulating layer 247a and the upper channel pad 249a.

A first horizontal insulating layer 292 may be disposed between the first and second channel structures CH1 and CH2 in an upper portion and the upper channel structures CH3 in an upper portion and may extend horizontally. The first horizontal insulating layer 292 may be disposed between the upper gate conductive layer 293 and the uppermost interlayer insulating layer 223. The first horizontal insulating layer 292 may also be a layer used as an etching stop layer when forming the upper channel structures CH3, and used when forming the connection pads 295.

The first horizontal insulating layer 292 may include an insulating material and may include a different material from the uppermost interlayer insulating layer 223. The first horizontal insulating layer 292 may be a hydrogen blocking layer and may include a material blocking or reducing diffusion of hydrogen (H). The first horizontal insulating layer 292 may include a nitride, and may include, for example, at least one of SiN, SiON, SiCN, or SiOCN.

The connection pads 295 may penetrate through the first horizontal insulating layer 292 between the first and second channel structures CH1 and CH2 and the upper channel structures CH3, thus electrically connecting the upper channel layers 240 and the upper channel layers 240c may to each other. The connection pads 295 may be formed by partially removing the first horizontal insulating layer 292 and may thus have upper surfaces that are coplanar with an upper surface of the first horizontal insulating layer 292. The connection pads 295 may be disposed in a form in which the upper channel pad layer 249 is partially recessed. However, the specific arrangement form of the connection pads 295 may be variously changed in example embodiments. The connection pads 295 may include a conductive material, for example, may include polycrystalline silicon.

The upper gate conductive layer 293 may be disposed in the X-Y plane within the first region R1 and may include a conductive material. The upper gate conductive layer 293 may include the same material as the gate electrodes 230, but may include doped polysilicon. When the upper gate conductive layer 293 includes doped polysilicon, the upper gate conductive layer 293 may be disposed to have a thickness greater than that of the gate electrodes 230.

The upper insulating regions SS may extend in the X-direction between the separation regions MS adjacent to each other on the X-Y plane. The upper insulating regions SS may penetrate through the upper gate conductive layer 293. The upper insulating regions SS may divide the upper gate conductive layer 293 in the Y-direction. The upper gate conductive layer 293 may be divided into a plurality of upper gate electrode regions 293e that are physically and electrically separated, by the upper insulating regions SS. Some of the upper insulating regions SS may be disposed to cut the upper gate conductive layer 293 in the Y-direction on both sides of the separation regions MS on the X-Y plane. Accordingly, on the separation regions MS, the upper gate conductive layer 293 may include an isolated upper dummy region 293d. The upper dummy region 293d may be physically and electrically insulated by having the upper insulating regions SS disposed on both sides thereof and having the separation region MS disposed in an upper portion thereof.

Accordingly, the upper dummy regions 293d may be disposed below the separation regions MS, and the separation regions MS and the upper insulating regions SS may be offset from each other in the Z-direction.

An insulation separation distance of the two upper insulating regions SS in the Y-direction, disposed on both sides of each separation region MS, may satisfies a first distance d1, and the first distance d1 may be greater than the lower width W4 of the separation region MS. Accordingly, a lower width W1 of the upper dummy region 293d disposed between the two upper insulating regions SS may be greater than the lower width W4 of the separation region MS. Within the first region R1, each separation region MS may have a smaller width so as to overlap the upper dummy region 293d in the Z-direction. The lower width W1 of the upper dummy region 293d in the Y-direction may be less than a width of the upper gate electrode region 293e in the Y-direction.

The upper insulating regions SS may gradually increase from a width Wb of an upper end thereof to a width Wt of a lower end thereof, and may have an inclined side surface. Upper ends of the upper insulating regions SS may be coplanar with an upper surface of the upper gate conductive layer 293, and lower ends of the upper insulating regions SS may be coplanar with a lower surface of the upper gate conductive layer 293. Accordingly, a length of the upper insulating regions SS in the Z-direction may be the same or substantially the same as a thickness of the upper gate conductive layer 293.

The width Wt of the lower end of the upper insulating regions SS may be less than a width of an upper portion of the upper channel structures CH3, ands may be, in some example embodiments, less than or equal to ½ of the width of the upper portion of the upper channel structures CH3. The upper insulating regions SS may be disposed so as to separate only the upper gate conductive layer 293, rather than being formed by recessing a portion of the channel structures CH.

Each of the upper insulating regions SS may include an upper separation insulating layer. The upper separation insulating layer may include an insulating material, and may include, for example, silicon oxide, silicon nitride, or silicon oxynitride.

A second horizontal insulating layer 294 may be disposed so as to cover the upper gate conductive layer 293. The second horizontal insulating layer 294 may be disposed below the upper gate conductive layer 293, and may cover a lower surface and a side surface of the upper gate conductive layer 293.

A first capping insulating layer 291 may be disposed below the second horizontal insulating layer 294, and the first capping insulating layer 291 and the second horizontal insulating layer 294 may be formed of an insulating material, and may be formed of a plurality of insulating layers.

In the first region R1, the semiconductor device 10 may include the first conductive layer 201 between a lower surface of the second conductive layer 202 and the stack structures GS1 and GS2. The first conductive layer 201 may include a semiconductor material. For example, the first conductive layer 201 may include a semiconductor material, such as a group IV semiconductor, a group III-V compound semiconductor, or a group II-VI compound semiconductor. For example, the group IV semiconductor may include silicon (Si), germanium (Ge), or silicon-germanium (SiGe). The first conductive layer 201 may function as a common source line CSL of the semiconductor device 10. The first conductive layer 201 may include a silicon layer, for example, a silicon layer having an N-type conductivity type. For example, the first conductive layer 201 may be provided as a crystalline semiconductor layer or an epitaxial layer, such as a single-crystal silicon layer or a polycrystalline silicon layer doped with impurities. As illustrated in the enlarged view of FIG. 4A, the first conductive layer 201 may cover a second portion of the channel structure CH and may be in direct contact with a protrusion 240a of the channel layer 240.

The first conductive layer 201 is a plate layer entirely covering the stack structures GS1 and GS2 and may be disposed so that an upper surface thereof has a flat surface. The first conductive layer 201 may have a thickness greater than a length of the protrusion 240a of the channel layer 240, and may be formed conformally along the shape of the channel structure CH.

The second conductive layer 202 may be disposed along the first conductive layer 201. The second conductive layer 202 may have a thickness less than that of the first conductive layer 201 and may be a conductive layer in contact with the first conductive layer 201. The second conductive layer 202 may include at least one of a metal-semiconductor compound, a metal-nitride, and a metal (e.g., tungsten (W), copper (Cu), and/or aluminum (Al)). The second conductive layer 202 may be aligned vertically with the first conductive layer 201.

The first and second conductive layers 201 and 202 may be source layers and may form a source structure together. The source structure may function as a common source line CSL of the semiconductor device 10.

A buffer layer (not illustrated) may be further formed on the second conductive layer 202. The buffer layer may be an oxide conformally covering the second conductive layer 202, and may include silicon oxide, silicon nitride, or the like.

The upper interconnection structures 271, 273, and 274 may electrically connect the gate electrodes 230 and the channel structures CH to the circuit elements 120 within the upper capping layer 290. The upper interconnection structures 271, 273, and 274 may be connected to channel studs 272 connected to the channel structures CH. The channel studs 272 disposed below the channel structure CH may be connected to the channel pads 249a of the upper channel structure CH3. The channel studs 272 connected to the channel structure CH3 may be electrically connected to the channel layer 240 through the channel pads 249a of the channel structures CH in the first region R1. In the second region R2, studs (not illustrated) may be connected to contact plugs connected to the gate electrode 230. The channel studs 272 may include a conductive material, and may include, for example, tungsten (W), copper (Cu), and/or aluminum (Al), and the channel studs 272 may further include a diffusion barrier layer 272b including at least one of titanium (Ti), titanium nitride (TiN), tantalum (Ta), tantalum nitride (TaN), or tungsten nitride (WN).

A first upper interconnection line 271 may be electrically connected to the channel studs 272, may include a plurality of bit lines BL extending in the Y-direction and spaced apart from each other by a predetermined (or, alternatively, desired, determined, or selected) pitch in the X-direction. A second upper interconnection line 274 may be disposed below the first upper interconnection line 271, and connecting vias 273 may be disposed between the second upper interconnection line 274 and the first upper interconnection line 271 and between the channel studs 272 and the first upper interconnection line 271. The upper interconnection structures 271, 273, and 274 may also include a conductive material, and may include, for example, tungsten (W), copper (Cu), and/or aluminum (Al), and each of the components may further include a diffusion barrier layer including at least one of titanium (Ti), titanium nitride (TiN), tantalum (Ta), tantalum nitride (TaN), or tungsten nitride (WN). According to example embodiments, the number of layers of the upper interconnection lines 271 and 274 included in the upper interconnection structures 271, 273, and 274 and an arrangement shape thereof may be variously changed.

The address studs 275 may be disposed by corresponding to the upper dummy regions 293d and may be disposed below a lower surface Sa of the upper dummy regions 293d.

Each address stud 275 may include an upper surface Sb and a lower surface and a side surface between the upper surface Sb and the lower surface. Each of the address studs 275 may be configured so that a width of the upper surface Sb is less than a width W2 of the lower surface, and a width thereof may increase toward the lower surface. The side surface may have an inclination due to a difference in width between the upper surface Sb and the lower surface, but the present disclosure is not limited thereto. A size and a shape of each of the address studs 275 may be greater than a size and a shape of the channel studs 272.

For example, the channel studs 272 may also include an upper surface and a lower surface, and a side surface between the upper surface and the lower surface. Each of the channel studs 272 may be configured so that a width of the upper surface is less than a width W3 of the lower surface, and a width thereof may increase toward the lower surface. The side surface may have an inclination due to a difference in the width of the upper surface and the lower surface, but the present disclosure is not limited thereto. Specifically, when the width W2 of a lower surface of each of the address studs 275 is the greatest, the width W3 of a lower surface of the channel studs 272 may also be the greatest, and the width W2 of the lower surface of the address studs 275 and the width W3 of the lower surface of the channel studs 272 may be the same or substantially the same. A length h2 of each of the address studs 275, that is, a length h2 in the Z-direction, may be greater than a length h1 of the channel studs 272. That is, the address studs 275 may extend in the Z-direction to penetrate through both the first capping insulating layer 291 and the second horizontal insulating layer 294, and the channel studs 272 may extend in the Z-direction to penetrate through only the first capping insulating layer 291. Accordingly, a width of the upper surface Sb of the address studs 275 may be less than a width of the upper surface of the channel studs 272, but the present disclosure is not limited thereto.

The lower surface of the address studs 275 and the lower surface of the channel studs 272 may be disposed on the same or substantially the same level. A distance between the address studs 275 and the nearest channel studs 272, among the channel studs 272, may satisfy a minimum distance or more. A minimum distance may be greater than a distance between the channel studs 272.

The address studs 275 and the channel studs 272 may include a conductive material, and may include, for example, tungsten (W), copper (Cu), and/or aluminum (Al), and each of the components may further include diffusion barrier layers 275b and 272b including at least one of titanium (Ti), titanium nitride (TiN), tantalum (Ta), tantalum nitride (TaN), or tungsten nitride (WN).

The upper capping layer 290 may include a plurality of capping insulating layers 291, 296, and 298, and may include a first capping insulating layer 291, a second capping insulating layer 296, and a third capping insulating layer 298, but the present disclosure but is not limited thereto. The first to third capping insulating layers 291, 296, and 298 are meant to be stacked in different orders in the process, and may include the same or substantially the same material. The first to third capping insulating layers 291, 296, and 298 may include at least one of SiCN, SiO, SiN, SiOC, SiON, or SiOCN.

A width W1 of a lower surface Sa of the upper dummy regions 293d may be greater than a width of the upper surface thereof, and a lower surface Sa of the upper dummy regions 293d may have a first width W1 in the Y-direction.

The second horizontal insulating layer 294 may be disposed to cover the lower surface Sa of the upper dummy regions 293d, and the first capping insulating layer 291 may be disposed to cover lower surfaces of the second horizontal insulating layer 294 and the upper channel structures CH3.

The address studs 275 and the channel studs 272 may be disposed by penetrating through the first capping insulating layer 291. The upper surface Sb of the address studs 275 may be in contact with the lower surface Sa of the upper dummy region 293d, but is not limited thereto, and may be disposed within the second horizontal insulating layer 294.

When a centerline of the width W1 of the lower surface Sa of the upper dummy region 293d in the Y-direction is defined as a reference line l0, if the centerline of the width of the upper surface Sb of the address studs 275 therebelow is defined as a first line l1, the reference line l0 and the first line l1 may be arranged to be coaxial. Accordingly, the address studs 275 may be disposed to be aligned in the Z-direction so as to be disposed in a center on the lower surface Sa of the upper dummy region 293d. An entire row of address studs 275 may overlap the upper dummy region 293d in the Z-direction, and the address studs 275 are offset from the upper insulating regions SS.

The second capping insulating layer 296 may be disposed below the first capping insulating layer 291. Among the connecting vias 273, first upper vias 273a penetrating through the second capping insulating layer 296 may be disposed. The first upper vias 273a may not be connected to the address studs 275, but may be connected to the channel studs 272.

The first upper vias 273a may be connected to the first interconnection lines 271. The first upper vias 273a may be connected to the first interconnection lines 271, for example, the bit lines BL, to apply an electrical signal to the channel structures CH. The address studs 275 may be spaced apart from the first interconnection lines 271 including the bit lines BL in the Z-direction. The second capping insulating layer 296 may be disposed between the address studs 275 and the first interconnection lines 271 including the bit lines BL.

The third capping insulating layer 298 may be disposed on the second capping insulating layer 296, and second upper vias 273b and the second interconnection lines 274 may be disposed within the third capping insulating layer 298 and may be connected to the first interconnection lines 271.

The upper bonding structure 280 may be connected to the upper interconnection structures 271, 273, and 274. For example, the channel studs 272 may be electrically connected to the upper bonding structure 280. The upper bonding structure 280 may include an upper bonding via 282, an upper bonding pad 284, and an upper bonding insulating layer 286. The upper bonding via 282 may be connected to the upper interconnection structure 271, 273, and 274. The upper bonding pad 284 may be connected to the upper bonding via 282. The upper bonding via 282 and the upper bonding pad 284 may include a conductive material, and may include, for example, tungsten (W), copper (Cu), and/or aluminum (Al), and each of the components may further include a diffusion barrier layer. The upper bonding insulating layer 286 may also function as a diffusion barrier layer of the upper bonding pad 284, and may include at least one of SiCN, SiO, SiN, SiOC, SiON, or SiOCN. The upper bonding insulating layer 286 may have a thickness thinner than a thickness of the upper bonding pad 284, but the present disclosure is not limited thereto.

Hereinafter, example embodiments of the present disclosure will be described with reference to FIGS. 5 to 8. FIGS. 5 to 7 are enlarged views of a semiconductor device according to example embodiments, and are enlarged views of a region corresponding to FIG. 4B.

Referring to FIG. 5, a semiconductor device 10a may be the same as that of FIG. 4B except for the arrangement of the address studs 275.

When a centerline of a width W1 of a lower surface Sa of the upper dummy regions 293d is defined as the reference line l0, if a centerline of a width of an upper surface Sb of the address studs 275 therebelow is defined as the first line l1, the address studs 275 may be disposed so that the first line l1 is offset from the reference line l0 by a second distance d2. Accordingly, the address studs 275 may be disposed below the lower surface Sa of the upper dummy regions 293d so that the address studs 275 are offset from a center thereof and close to one side surface thereof. Accordingly, the address studs 275 may be disposed to be offset so as to be closer to the upper insulating region SS on one side thereof. At least a portion of the upper surface Sb of the address studs 275 may overlap the upper insulating regions SS, but the present disclosure is not limited thereto.

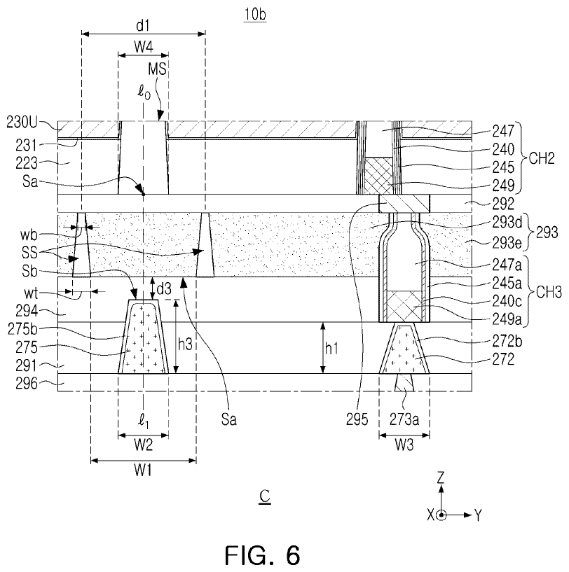

Referring to FIG. 6, a semiconductor device 10b may be the same as that of FIG. 4B except for the size of the address studs 275.

Each of the address studs 275 may include an upper surface Sb and a lower surface, and a side surface between the upper surface Sb and the lower surface. Each address stud 275 may be configured so that a width of the upper surface Sb is less than the width W2 of the lower surface, and a width thereof may increase toward the lower surface. The side surface may have an inclination due to a difference in the width of the upper surface Sb and the lower surface, but the present disclosure is not limited thereto. A size and a shape of each address stud 275 may be different from a size and a shape of the channel studs 272. The channel studs 272 may also include an upper surface and a lower surface, and a side surface between the upper surface and the lower surface. Each of the channel studs 272 may be configured so that a width of the upper surface is less than a width of the lower surface W3, and a width thereof may increase toward the lower surface. The side surface may have an inclination due to the difference in the width of the upper surface and the lower surface, but the present disclosure is not limited thereto. Specifically, when a width of the lower surface W2 of each of the address studs 275 is the greatest, a width of the lower surface W3 of the channel studs 272 may also be the greatest, and the width of the lower surface W2 of the address studs 275 may be same as the width of the lower surface W3 of the channel studs 272. The width of the upper surface Sb of the address studs 275 may be less than the width of the upper surface of the channel studs 272, and a length h3 of the address studs 275, e.g., a length h3 in the Z-direction, may be greater than or equal to the length h1 of the channel studs 272, but may be greater than a length of the upper vias 273.

Accordingly, an upper end of the address studs 275 may be disposed within the second horizontal insulating layer 294, and the lower surface of the address studs 275 may be coplanar with the lower surface of the channel studs 272 and may be coplanar with a lower surface of the first capping insulating layer 291. However, the upper surface Sb of the address studs 275 may be physically separated from the lower surface Sa of the upper dummy region by a third distance d3 in the Z-direction, and a portion of the second horizontal insulating layer 294 may be disposed in the separated space.

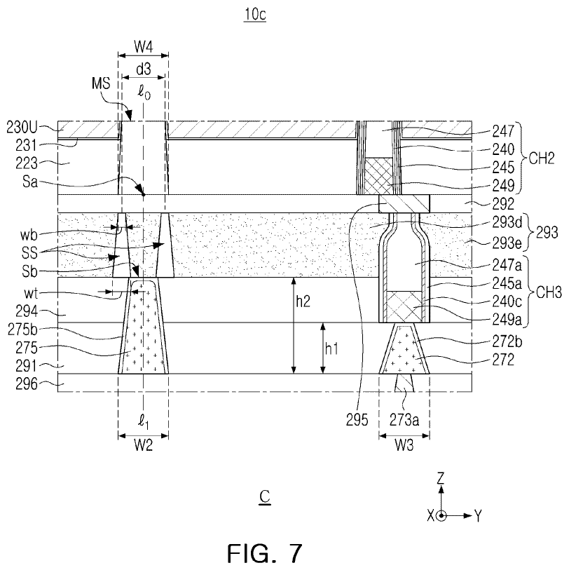

Referring to FIG. 7, a semiconductor device 10c may be the same as that of FIG. 4b except for the size of the upper dummy region.

In the semiconductor device of FIG. 7, the upper dummy region 293d may overlap the separation regions MS in the Z-direction, but a separation distance d3 between the upper insulating regions SS on both sides of the upper dummy region 293d, e.g., a pitch, may be equal to or less than a width W4 of the lower surface of the separation region MS.

Accordingly, the width of the lower surface of the upper dummy region 293d may be less than the width W3 of the lower surface of the separation region MS. However, a reference line l0, which is a center of the width of the lower surface of the upper dummy region 293d may be coaxial with a center of the width W4 of the lower surface of the separation region MS. In this case, the address studs 275 may be disposed to form a first center line l1 of the width of the upper surface Sb so that the address studs 275 is coaxial with the reference line l0 of the upper dummy region 293d. In this case, as an upper end of the address studs 275 has a narrower width than that of a lower portion thereof, the address studs 275 may be disposed to be offset from the upper insulating regions SS, and may be electrically/physically separated from the upper gate electrode regions 293e.

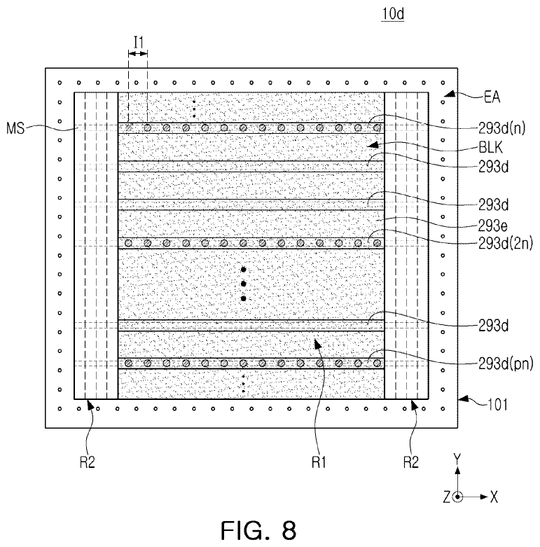

A semiconductor device 10d of FIG. 8 is the same as the semiconductor device of FIG. 1 to FIG. 4B except for an arrangement of the address studs 275.

Referring to FIG. 8, the upper dummy regions 293d in which the address studs 275 are disposed may be limited to some of the upper dummy regions 293d. Among the upper dummy regions 293d, upper dummy regions 293d in which the address studs 275 are disposed may be defined as address upper dummy regions 293d.

The address upper dummy regions 293d may be defined as n-th upper dummy regions 293d in the Y-direction. n may be a natural number such as 50, 100, or 200, but the present disclosure is not limited thereto.

In this manner, the address studs 275 may be not arranged on all the upper dummy regions 293d, but may be arranged only on some of the upper dummy regions 293d, so that an error position in the Y-direction may be more clearly identified.

An arrangement of the address studs 275 on each address upper dummy region 293d may be uniformly arranged based on the first separation distance I1, so that during an error inspection, the arrangement of the address studs 275 may be reviewed to (e.g., rapidly, or easily) confirm not only a position thereof in the X-direction but also a position thereof in the Y-direction, e.g., a position of the memory block BLK.

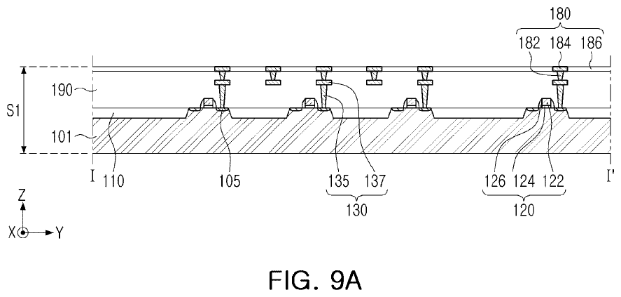

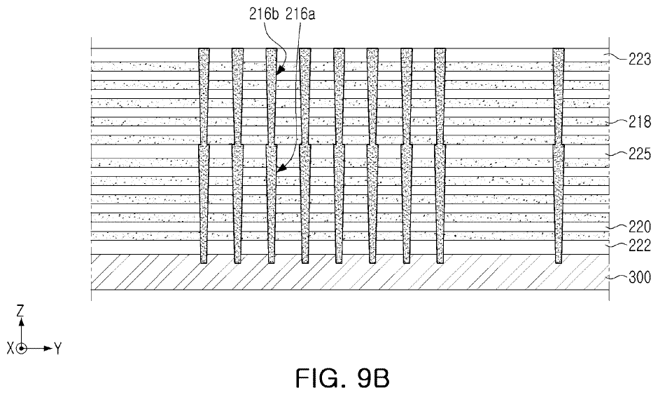

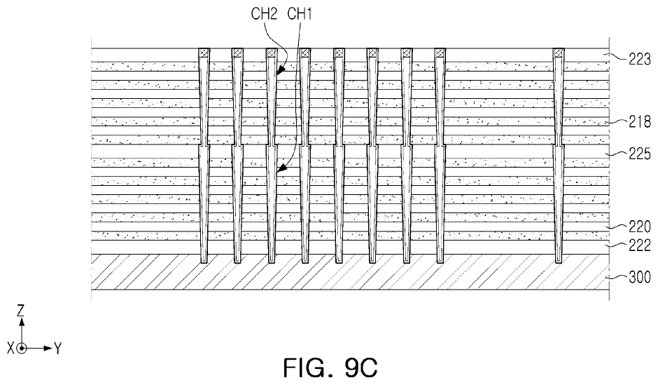

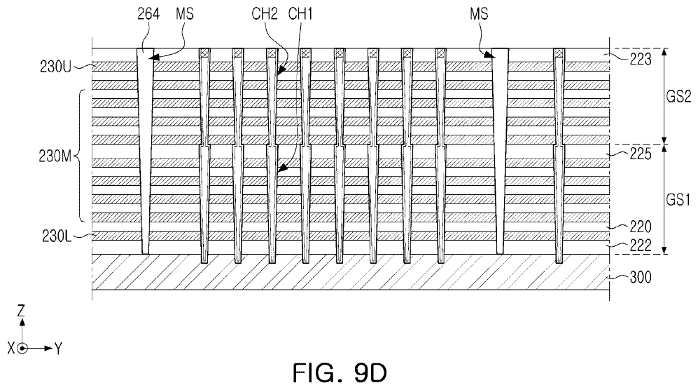

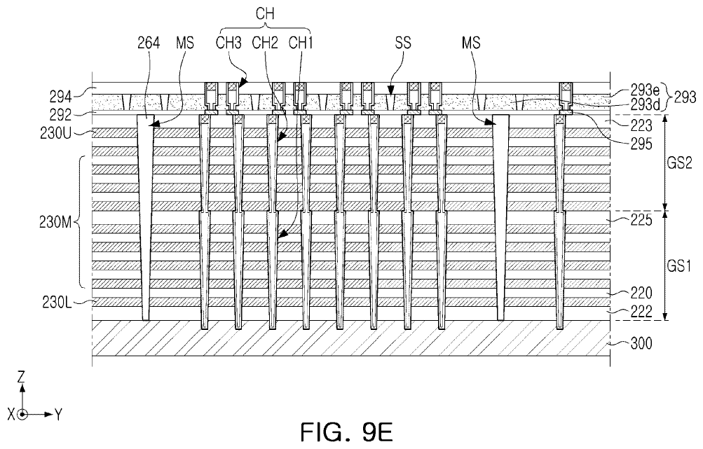

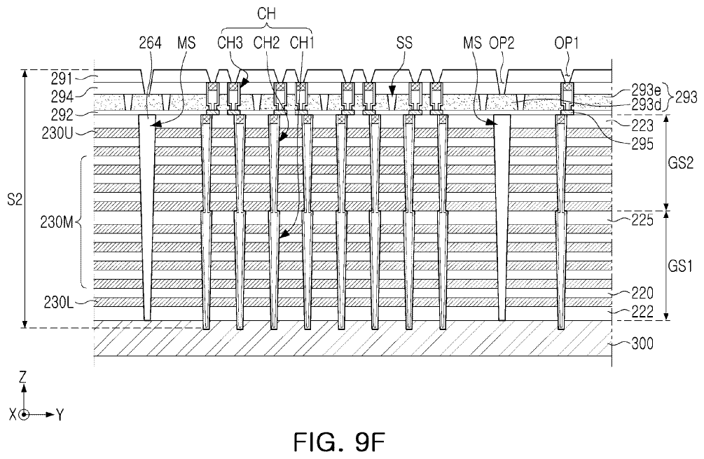

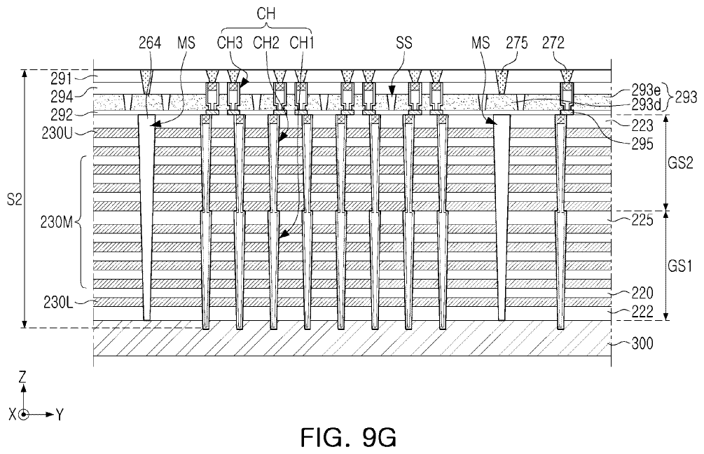

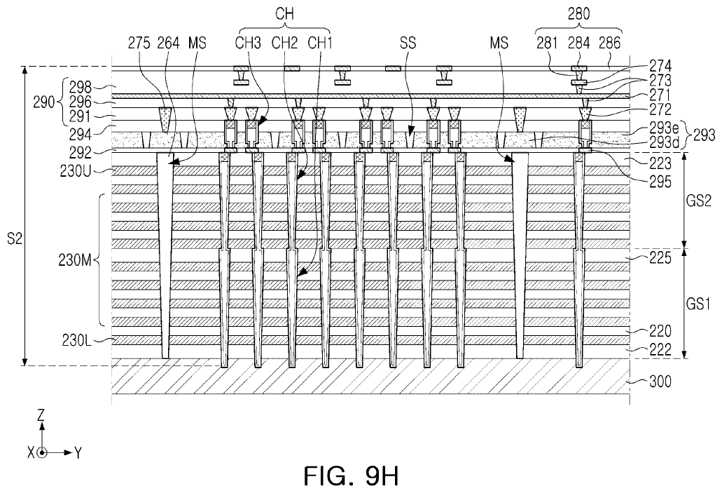

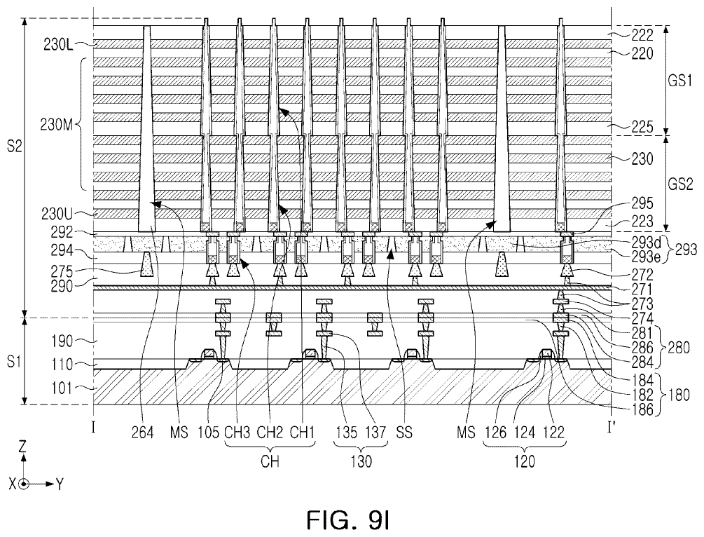

FIGS. 9A to 9I are schematic cross-sectional views illustrating a method of manufacturing a semiconductor device according to example embodiments. FIGS. 9A to 9I illustrate regions corresponding to FIG. 3.

Referring to FIG. 9A, a first semiconductor structure S1 (PERI) including circuit elements 120, a lower interconnection structure 130, a lower bonding structure 180, and a lower capping layer 190, which are included in a peripheral circuit region PERI, may be formed on a first substrate 101.

First, element isolation layers 110 may be formed in the first substrate 101, and a circuit gate dielectric layer 122 and a circuit gate electrode 124 may be sequentially formed on the first substrate 101. The element isolation layers 110 may be formed, for example, by a shallow trench isolation (STI) process. The circuit gate dielectric layer 122 may be formed on the first substrate 101, and the circuit gate electrode 124 may be formed on the circuit gate dielectric layer 122. The circuit gate dielectric layer 122 and the circuit gate electrode 124 may be formed using atomic layer deposition (ALD) or chemical vapor deposition (CVD). The circuit gate dielectric layer 122 may be formed of silicon oxide, and the circuit gate electrode 124 may be formed of at least one of polycrystalline silicon or a metal silicide layer, but the present disclosure is not be limited thereto. Next, spacer layers 126 may be formed on both sidewalls of the circuit gate dielectric layer 122 and the circuit gate electrode 124, and impurities may be injected into the active region of the first substrate 101 on both sides of the circuit gate electrode 124, thus forming source/drain regions 105.

In the lower interconnection structure 130, lower contact plugs 135 may be formed by forming a portion of the lower capping layer 190, etching and removing the portion thereof, and then, filling the removed portion with a conductive material. The lower interconnection lines 137 may be formed, for example, by depositing a conductive material and then patterning the same.

In the lower bonding structure 180, the lower bonding via 182 may be formed by forming a portion of the lower capping layer 190, etching and removing the portion, and then, filling the removed portion with a conductive material. The lower bonding pads 184 may be formed, for example, by depositing a conductive material and then patterning the same. The lower bonding structures 180 may be formed, for example, by a deposition process or a plating process. The lower bonding insulating layer 186 may be formed by covering a portion of an upper surface and a side surface of the lower bonding pad 184, and then performing a planarization process until an upper surface of a lower bonding pad 184 is exposed.

The lower capping layer 190 may be formed of a plurality of insulating layers. The lower capping layer 190 may be a portion in each operation of forming the lower interconnection structure 130 and the lower bonding structure 180. Accordingly, the first semiconductor structure S1, which is a peripheral circuit region PERI, may be formed.

Referring to FIG. 9B, a manufacturing process of the second semiconductor structure S2 CELL may begin.

Referring to FIG. 9B, the manufacturing process of the second semiconductor structure S2 CELL may begin. On a base substrate 300, sacrificial insulating layers 218 and interlayer insulating layers 220 may be alternately stacked to form a mold structure, and sacrificial vertical structures 216a and 216b may be formed in a position in which each vertical structure is formed, respectively.

The lower mold structure may be formed on the base substrate 300 at a height at which the first channel structures CH1 (see FIG. 3) are disposed. The base substrate 300 may include a semiconductor material, for example, a group IV semiconductor, a group III-V compound semiconductor, or a group II-VI compound semiconductor.

The sacrificial insulating layers 218 may be layers in which at least a portion thereof is replaced with a portion of the gate electrodes 230 (see FIG. 3) through a subsequent process. The sacrificial insulating layers 218 may be formed of a different material from the interlayer insulating layers 220. For example, an interlayer insulating layer 220 and uppermost, intermediate, and lowermost interlayer insulating layers 223, 225, and 222 may be formed of at least one of silicon oxide or silicon nitride, and the sacrificial insulating layers 218 may be formed of a different material from the interlayer insulating layer 220 selected from silicon, silicon oxide, silicon carbide, and silicon nitride. In example embodiments, thicknesses of the interlayer insulating layers 220 may not all be the same. Additionally, the thicknesses of the interlayer insulating layers 220 and the sacrificial insulating layers 218 and the number of films included therein may be variously changed from those illustrated.

The interlayer insulating layers 220 and the sacrificial insulating layers 218 included in the lower mold structure are alternately stacked on the base substrate 300.

When a gate pad region is formed in the second regions R2, a photolithography process and an etching process for the sacrificial insulating layers 218 and the interlayer insulating layers 220 may be performed repeatedly. However, in example embodiments, a specific shape of the gate pad region may be variously changed.

First vertical sacrificial layers 216a may be formed in a position corresponding to a lower portion of the first channel structures CH1 in the first region R1. The first vertical sacrificial layers 216a may be formed by forming holes to penetrate through the lower mold structure, depositing a sacrificial layer material in the holes, and performing a planarization process. Vertical sacrificial layers including the first vertical sacrificial layers 216a may include, for example, at least one of TiN and polycrystalline silicon.

Next, the sacrificial insulating layers 218 and interlayer insulating layers 220 included in an upper mold structure may be alternately stacked on the lower mold structure, and second vertical sacrificial layers 216b may be formed.

Each component of the upper mold structure may be formed in the same manner as a formation method of the lower mold structure. The second vertical sacrificial layers 216b may be formed to be connected to the first vertical sacrificial layers 216a, respectively. The second vertical sacrificial layers 216b may be formed by depositing the same material as the first vertical sacrificial layers 216a, for example, polycrystalline silicon.

Accordingly, the plurality of vertical sacrificial layers 216a and 216b included in all of the vertical structures of FIG. 3, the first and second channel structures CH1 and CH2, may be formed simultaneously (e.g., at or about at the same time).

As illustrated in FIG. 9C, on the base substrate 300, first and second channel structures CH1 and CH2 penetrating through the mold structure of the sacrificial insulating layers 218 and the interlayer insulating layers 220 may be formed.

The first and second channel structures CH1 and CH2 may be formed by forming upper holes on the vertical sacrificial layers 216a and 216b, removing the vertical sacrificial layers 216a and 216b to form hole-shaped channel holes, and then filling the channel holes with a plurality of layers. The plurality of layers may include an information storage structure 245, a channel layer 240, a buried insulating layer 247, and a channel pad 249. The upper channel holes of the channel holes may be formed by anisotropically etching the upper stack structure of the sacrificial insulating layers 218 and the interlayer insulating layers 220 using a separate mask layer. The lower channel holes of the channel holes may be formed by removing the vertical sacrificial layer exposed through the upper channel holes.

Due to a height of the mold structure, sidewalls of the first and second channel structures CH1 and CH2 may not be perpendicular to an upper surface of the base substrate 300. The first and second channel structures CH1 and CH2 may be formed to recess a portion of the base substrate 300 according to a depth of the channel hole.

The information storage structure 245 may be formed to have a uniform thickness. The information storage structure 245 may be formed in whole or in part in this operation, and a portion extending vertically to the base substrate 300 along the channel structures CH may be formed in this operation. The channel layer 240 may be formed on the information storage structure 245 within the channel structures CH. The buried insulating layer 247 may be formed to fill the channel structures CH and may be formed of an insulating material. The channel pad 249 may be made of a conductive material, and may be formed, for example, of polycrystalline silicon. After the first and second channel structures CH1 and CH2 are formed, contact plugs may be formed in the second region R2.

Referring to FIG. 9D, gate electrodes 230 may be formed. After forming separation openings in a position of the separation regions MS, the sacrificial insulating layers 218 may be selectively removed with respect to the interlayer insulating layers 220 through wet etching within the separation openings, and gate electrodes 230 may be formed.

The gate electrodes 230 may be formed by depositing a conductive material in regions from which the sacrificial insulating layers 218 are removed. The conductive material may include a metal, polycrystalline silicon, or a metal silicide material. In some example embodiments, a portion of the gate dielectric layer may be formed before forming the gate electrodes 230.

After forming the gate electrodes 230, gate separation insulating layers 264 may be formed within the openings formed to correspond to the separation regions MS.

Referring to FIG. 9E, upper channel structures CH3 may be formed.

A first horizontal insulating layer 292, an upper gate conductive layer 293, and a second horizontal insulating layer 294 may be formed, and upper channel structures CH3 penetrating through the upper gate conductive layer 293 may be formed.

The first horizontal insulating layer 292 may be formed on the first and second channel structures CH1 and CH2. The first horizontal insulating layer 292 may be formed by patterning the upper gate conductive layer 293. The upper gate conductive layer 293 may include a material different from other gate electrodes 230, but the present disclosure is not limited thereto. For example, the upper gate conductive layer 293 may include doped polysilicon.

Upper insulating regions SS may be formed to divide the upper gate conductive layer 293 into an upper gate electrode region 293e and an upper dummy region 293d. The upper insulating regions SS may be formed by forming an opening to extend in the X-direction and filling the opening with an insulating material. Next, a second horizontal insulating layer 194 may be further formed.

In order to form the upper channel structures CH3, upper channel holes penetrating through the upper gate electrode region 293e of the upper gate conductive layer 293 and the second horizontal insulating layer 194 may be formed, and then second channel dielectric layers 245a and sacrificial layers may be sequentially formed. Next, lower holes penetrating through the second channel dielectric layers 245a and the sacrificial layers on bottom surfaces of the upper channel holes and extending to the horizontal insulating layer 292 may be formed, and some of the horizontal insulating layer 292 exposed through the lower holes may be removed to expose channel pads 249a. After connection pads 295 in regions in which the horizontal insulating layer 292 is removed are formed and the sacrificial layers are removed, a second channel layer 240c, a second channel buried layer 247a, and a second channel pad 249a are sequentially formed in each of the upper channel holes, thereby forming upper channel structures CH3. Each layer may be formed in the same manner as in the first channel structures CH1. The second channel buried layer 247a may be connected to the connection pads 295 in a lower end thereof.

Referring to FIG. 9F, stud holes OP1 and OP2 for forming channel studs 272 and address studs 275 may be formed.

As illustrated in FIG. 9F, a first capping insulating layer 291 may be formed on the second horizontal insulating layer 294 by covering an entire upper surface of the upper channel structures CH3.

In the first capping insulating layer 291, a channel stud hole OP1 exposing the channel pad 249a of each upper channel structure CH3 and an address stud hole OP2 exposing an upper surface of the upper dummy region 293d may be simultaneously formed.

The stud holes OP1 and OP2 may be formed by removing a corresponding regions from the upper surface of the first capping insulating layer 291 by an etching process, and a depth of the address stud hole OP2 may be formed to be longer than that of the channel stud hole OP1.

Referring to FIG. 9G, channel studs 272 and address studs 275 may be formed.

Diffusion barrier layers 272b and 275b may be stacked along side surfaces of the channel stud hole OP1 and the address stud hole OP2, and a conductive material may be stacked by filling the channel stud hole OP1 and the address stud hole OP2 within the diffusion barrier layers 272b and 275b, thereby forming channel studs 272 and address studs 275. Depending on the shape of the channel stud hole OP1 and the address stud hole OP2, a width of an upper end thereof may be greater than a width of a lower end thereof, and may have an inclined side surface. Accordingly, address studs 275 may be formed on the upper dummy region 293d.

Referring to FIG. 9H, upper interconnection structures 271, 273, and 274 may be formed on the channel studs 272 and the address studs 275.

First, a second capping insulating layer 296 may be formed by covering the channel studs 272 and the address studs 275, and a portion of the second capping insulating layer 296 may be removed to form a first upper via hole exposing upper surfaces of the channel studs 272. The first upper via hole may be formed to have a smaller size than that of the channel stud hole OP2, and may not be formed on the address studs 275.

A diffusion barrier and a conductive material may be formed in the first upper via hole to form first upper vias 273a connected to the channel studs 272.

Next, a third capping insulating layer 298 covering the first upper vias 273a may be formed, and upper interconnection structures 271, 273, and 274 including first upper interconnection lines 271, second upper vias 273b and second upper interconnection lines 274 connected to the first upper vias 273a may be formed. The third capping insulating layer 298 may be implemented as a multilayer structure, and the upper interconnection structures 271, 273, and 274 may be formed by stacking a diffusion barrier and a conductive material, in the same manner as the first upper vias 273a.

An upper bonding structure 280 may be formed on the upper interconnection structures 271, 273, and 274. The upper bonding structure 280 may be formed in a similar manner to forming the lower bonding structure 180. In this manner, a second semiconductor structure S2, which is a memory cell structure CELL, may be formed. However, during the manufacturing process of the semiconductor device 10, the second semiconductor structure S2 may further include a base substrate 300.

Referring to FIG. 9I, a first semiconductor structure S1, which is a peripheral circuit structure PERI, and a second semiconductor structure S2, which is a memory cell structure CELL, may be bonded to each other.

The first semiconductor structure S1 and the second semiconductor structure S2 may be connected by bonding a lower bonding pad 184 and an upper bonding pad 284 by applying pressure thereto. The lower bonding insulating layer 186 and the upper bonding insulating layer 286 may be bonded and connected by applying pressure thereto. The second semiconductor structure S2 may be bonded on the first semiconductor structure S1 so that the upper bonding pad 284 faces downwardly. The first semiconductor structure S1 and the second semiconductor structure S2 may be directly bonded to each other without the intervention of an adhesive such as a separate adhesive layer.

In a state in which the first semiconductor structure S1 and the second semiconductor structure S2 are bonded to each other, the base substrate 300 exposed to an upper portion of the second semiconductor structure S2 may be removed, and lower ends of the channel structures CH may be exposed. In this case, the information storage structure 245 on the second portion of the exposed channel structure CH may be removed. The information storage structure 245 may be removed by a photolithography process and an etching process such as wet etching and/or dry etching. Accordingly, in a second portion of the channel structure CH protruding onto the stack structures GS1 and GS2, the channel layer 240 are may be exposed so that a protrusion 240a may be disposed. Accordingly, the channel layer 240 of the second portion may be in direct contact with the first conductive layer 201.

Next, as illustrated in FIG. 3, the first conductive layer 201 may be formed to cover the entire cell region R1. The first conductive layer 201 may be formed by depositing a semiconductor layer, specifically a crystalline silicon layer, for example, a polycrystalline silicon layer. The first conductive layer 201 may be formed to have a bend along protruding channel structures CH, but may be formed at a predetermined (or, alternatively, desired, determined, or selected) thickness so that an upper surface thereof is flat. The second conductive layer 202 may be formed on the first conductive layer 201. Specifically, the second conductive layer 202 may be formed as a multilayer. A buffer layer may be formed conformally by covering the entire second conductive layer 202, and an oxide film, for example, a silicon oxide film, may be formed as the buffer layer.

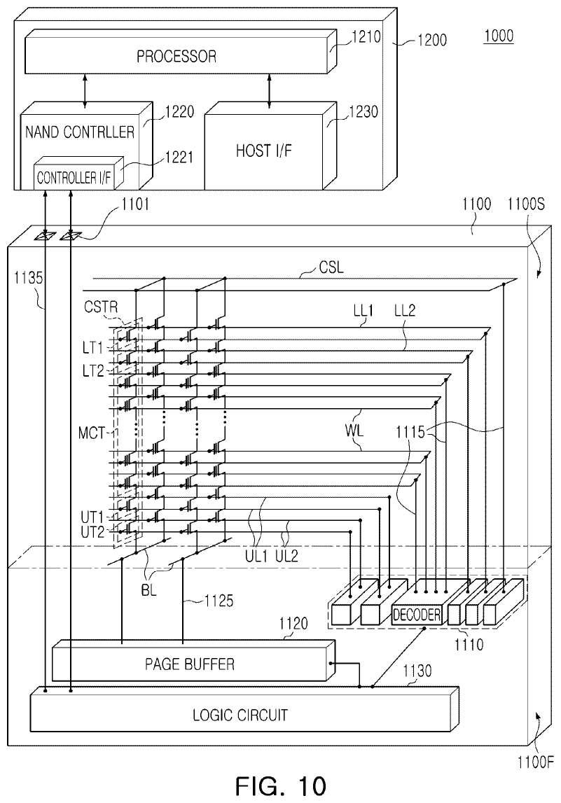

FIG. 10 is a view schematically illustrating a data storage system including a semiconductor device according to example embodiments.

Referring to FIG. 10, a data storage system 1000 may include a semiconductor device 1100 and a controller 1200 electrically connected to the semiconductor device 1100. The data storage system 1000 may be a storage device including one or more semiconductor devices 1100 or an electronic device including the storage device. For example, the data storage system 1000 may be a solid state drive device (SSD), a Universal Serial Bus (USB), a computing system, a medical device, or a communication device, including one or more semiconductor devices 1100.

The semiconductor device 1100 may be a nonvolatile memory device, and may be, for example, a NAND flash memory device described above with reference to FIGS. 1 to 8. The semiconductor device 1100 may include a first semiconductor structure 1100F and a second semiconductor structure 1100S on the first semiconductor structure 1100F. According to example embodiments, the first semiconductor structure 1100F may be disposed next to the second semiconductor structure 1100S. The first semiconductor structure 1100F may be a peripheral circuit structure including a decoder circuit 1110, a page buffer 1120, and a logic circuit 1130. The second semiconductor structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second semiconductor structure 1100S, each memory cell string CSTR may include lower transistors LT1 and LT2 adjacent to a common source line CSL, upper transistors UT1 and UT2 adjacent to a bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed according to example embodiments.

According to example embodiments, the upper transistors UT1 and UT2 may include string select transistors, and the lower transistors LT1 and LT2 may include ground select transistors. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

According to example embodiments, the lower transistors LT1 and LT2 may include ground select transistors LT1 and LT2 connected in series. The upper transistors UT1 and UT2 may include string select transistors UT1 and UT2 connected in series.

The common source line CSL, the first and second gate lower lines LL1 and LL2, the word lines WL and the first and second gate upper lines UL1 and UL2 may be electrically connected to the decoder circuit 1110 through first interconnection lines 1115 extending from the first semiconductor structure 1100F to the second semiconductor structure 1100S. The bit lines BL may be electrically connected to the page buffer 1120 through second interconnection lines 1125 extending from the first semiconductor structure 1100F to the second semiconductor structure 1100S.

In the first semiconductor structure 1100F, the decoder circuit 1110 and the page buffer 1120 may perform a control operation for at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 via an input/output interconnection line 1135 extending from the first semiconductor structure 1100F to the second semiconductor structure 1100S.

The controller 1200 may include a processor 1210, a NAND controller 1220, and a host interface 1230. According to example embodiments, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a predetermined (or, alternatively, desired, determined, or selected) firmware and may control the NAND controller 1220 to access the semiconductor device 1100. The NAND controller 1220 may include a NAND interface 1221 processing communication with the semiconductor device 1100. Through the NAND interface 1221, control commands for controlling the semiconductor device 1100, data to be written to the memory cell transistors MCT of the semiconductor device 1100, data to be read from the memory cell transistors MCT of the semiconductor device 1100, and the like, may be transmitted. The host interface 1230 may provide a communication function between the data storage system 1000 and an external host. When receiving a control command from the external host through the host interface 1230, the processor 1210 can control the semiconductor device 1100 in response to the control command.

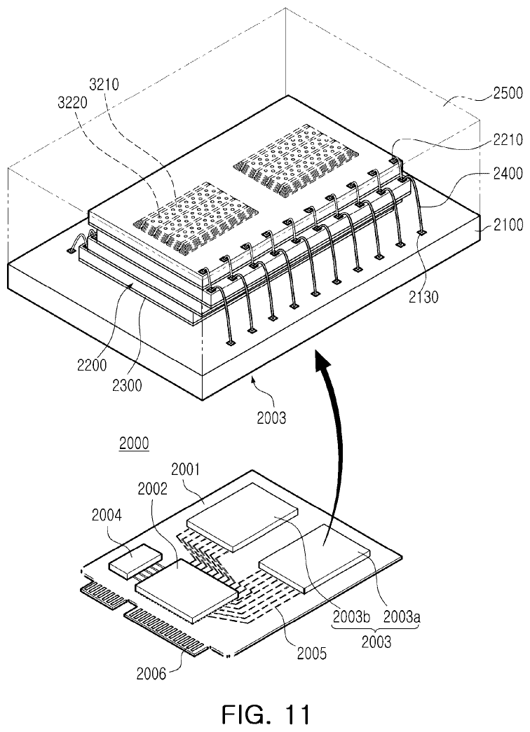

FIG. 11 is a perspective view schematically illustrating a data storage system including a semiconductor device according to some example embodiments.

Referring to FIG. 11, a data storage system 2000 according to some example embodiments of the present disclosure may include a main board 2001, a controller 2002 mounted on the main board 2001, one or more semiconductor packages 2003, and a DRAM 2004. The semiconductor package 2003 and the DRAM 2004 may be connected to each other with the controller 2002 by interconnection patterns 2005 formed on the main board 2001.

The main board 2001 may include a connector 2006 including a plurality of pins coupled to the external host. The number and arrangement of the plurality of pins in the connector 2006 may vary depending on the communication interface between the data storage system 2000 and the external host. According to example embodiments, the data storage system 2000 may communicate with the external host according to any one of the following interfaces: Universal Serial Bus (USB), Peripheral Component Interconnect Express (PCI-Express), Serial Advanced Technology Attachment (SATA), M-Phy for Universal Flash Storage (UFS). According to example embodiments, the data storage system 2000 may operate by power supplied from the external host through the connector 2006. The data storage system 2000 may further include a Power Management Integrated Circuit (PMIC) distributing power supplied from the external host to the controller 2002 and the semiconductor package 2003.

The controller 2002 may write data to the semiconductor package 2003 or may read data from the semiconductor package 2003, and may improve the operation speed of the data storage system 2000.

The DRAM 2004 may be a buffer memory for alleviating a speed difference between the semiconductor package 2003, which is a data storage space, and the external host. The DRAM 2004 included in the data storage system 2000 may also operate as a kind of cache memory, may also provide a space for temporarily storing data in a control operation for the semiconductor package 2003. When the data storage system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 that electrically connects the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each semiconductor chip 2200 may include an input/output pad 2210. The input/output pad 2210 may correspond to the input/output pad 1101 of FIG. 15. Each of the semiconductor chips 2200 may include gate stack structures 3210 and channel structures 3220. Each of the semiconductor chips 2200 may include the semiconductor device described above with reference to FIGS. 1 to 8.

According to example embodiments, the connection structure 2400 may be a bonding wire that electrically connects the input/output pad 2210 and the package upper pads 2130. Accordingly, in each of the first and second semiconductor packages 2003a and 2003b, the semiconductor chips 2200 may be electrically connected to each other in a bonding wire manner, and may be electrically connected to the package upper pads 2130 of the package substrate 2100. According to example embodiments, in each of the first and second semiconductor packages 2003a and 2003b, the semiconductor chips 2200 may be electrically connected to each other by a connection structure including a through-silicon via (TSV), instead of a connection structure 2400 in a bonding wire manner.

According to example embodiments, the controller 2002 and the semiconductor chips 2200 may be included in one package. According to some example embodiments, the controller 2002 and the semiconductor chips 2200 may be mounted on a separate interposer substrate different from a main board 2001, and the controller 2002 and semiconductor chips 2200 may be connected to each other by wiring formed on the interposer substrate.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Any or all of the elements described with reference to the figures may communicate with any or all other elements described with reference to figures. For example, any element may engage in one-way and/or two-way and/or broadcast communication with any or all other elements in the figures, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

The present disclosure is not limited to the above-described example embodiments and the accompanying drawings but is defined by the appended claims. Therefore, those of ordinary skill in the art may make various replacements, modifications, or changes, and combinations of example embodiments without departing from the scope of the present disclosure defined by the appended claims, and these replacements, modifications, or changes should be construed as being included in the scope of the present disclosure.

What is claimed is:

1. A semiconductor device, comprising:
a first semiconductor structure including a first substrate, circuit elements on the first substrate, a lower interconnection structure electrically connected to the circuit elements, and a lower bonding structure connected to the lower interconnection structure; and
a second semiconductor structure including an upper bonding structure bonded to the lower bonding structure on the first semiconductor structure,
the second semiconductor structure including
a conductive layer;
memory gate electrodes spaced apart from each other and stacked in a first direction below the conductive layer, the first direction perpendicular to an upper surface of the conductive layer;
first channel structures including a channel layer and penetrating through the memory gate electrodes in the first direction;
a first horizontal insulating layer below the memory gate electrodes and the first channel structures;
a selection gate conductive layer below the first horizontal insulating layer and including selection gate electrode regions overlapping the first channel structures in the first direction and dummy regions;
insulating regions extending in a second direction penetrating through the selection gate conductive layer, and spaced apart from each other in a third direction to separate the selection gate electrode regions and the dummy regions, the second direction being perpendicular to the first direction, and the third direction being perpendicular to the second direction;
second channel structures penetrating through the selection gate electrode regions and electrically connected to the first channel structures, respectively;
address studs spaced apart from each other by a first separation distance in the second direction below the dummy regions;
channel studs below the second channel structures; and
upper interconnection structures below the selection gate conductive layer, connected to the channel studs, and spaced apart from the address studs.

2. The semiconductor device of claim 1, further comprising:
separation regions penetrating through the memory gate electrodes, extending in the second direction, and spaced apart from each other in the third direction,
wherein each of the separation regions overlaps each of the dummy regions in the first direction.

3. The semiconductor device of claim 2,
wherein a width of a lower surface of each of the separation regions in the third direction is less than a width of a lower surface of each of the dummy regions in the third direction.

4. The semiconductor device of claim 2, wherein
the insulating regions are on both sides of each of the dummy regions, and
the insulating regions are offset from the separation regions in the first direction.

5. The semiconductor device of claim 1, wherein
each of the address studs includes an upper surface, a lower surface, and a side surface between the upper surface and the lower surface,
each of the channel studs includes an upper surface, a lower surface, and a side surface between the upper surface and the lower surface, and
the lower surface of each of the address studs is on a same level as the lower surface of each of the channel studs.

6. The semiconductor device of claim 5, wherein
a lower surface of each of the dummy regions and the upper surface of the address studs are in contact with each other, and
a width of the lower surface of each of the dummy regions is greater than a width of the lower surface of each of the address studs.

7. The semiconductor device of claim 5,
wherein a first reference line in the first direction, passing through a center of the lower surface of each of the address studs, is coaxial with a second reference line passing through a center of a width of each of the dummy regions in the third direction.

8. The semiconductor device of claim 5,
wherein a first reference line in the first direction, passing through a center of the upper surface of each of the address studs, is offset with respect to a second reference line passing through a center of a width of each of the dummy regions in the third direction.

9. The semiconductor device of claim 1,
wherein a length of each of the address studs in the first direction is greater than a length of each of the channel studs in the first direction.

10. The semiconductor device of claim 1,
wherein a width of a lower surface of each of the address studs is same as a width of a lower surface of each of the channel studs.

11. The semiconductor device of claim 1, wherein
the upper interconnection structures include bit lines connected to the channel studs and extending in the third direction, and spaced apart from each other in the second direction, and
the first separation distance is a multiple of pitches of the bit lines.

12. The semiconductor device of claim 1,
wherein a lower surface of each of the dummy regions is spaced apart from an upper surface of each of the address studs in the first direction.

13. The semiconductor device of claim 12, further comprising:
a second horizontal insulating layer between the lower surface of each of the dummy regions and the upper surface of each of the address studs.

14. A semiconductor device, comprising:
a first semiconductor structure including
a first substrate,
circuit elements on the first substrate,
a lower interconnection structure electrically connected to the circuit elements, and
a lower bonding structure connected to the lower interconnection structure; and
a second semiconductor structure including
an upper bonding structure bonded to the lower bonding structure on the first semiconductor structure,
a conductive layer;
gate electrodes including memory gate electrodes and a selection gate electrode spaced apart from each other and stacked in a first direction below the conductive layer, the first direction perpendicular to an upper surface of the conductive layer;
channel structures including a channel layer, the channel structures penetrating through the gate electrodes in the first direction;
insulating regions extending in a second direction penetrating through the selection gate electrode, and spaced apart from each other in a third direction to separate the selection gate electrode into selection gate electrode regions and dummy regions, the second direction perpendicular to the first direction, and the third direction being perpendicular to the second direction;
address studs spaced apart from each other by a first separation distance in the second direction below at least one dummy region among the dummy regions; and
channel studs below the channel structures.

15. The semiconductor device of claim 14,
wherein the address studs are below n-th dummy regions in the third direction among the dummy regions.

16. The semiconductor device of claim 14, further comprising:
a first horizontal insulating layer between the memory gate electrodes and the selection gate electrode; and
a second horizontal insulating layer below the selection gate electrode,
wherein the address studs penetrate through the second horizontal insulating layer and contact lower surfaces of the dummy regions.

17. The semiconductor device of claim 14,
wherein some of the address studs are arranged in a straight line in the third direction.

18. The semiconductor device of claim 14, further comprising:
an upper interconnection structure connected to the channel studs and spaced apart from the address studs,
wherein the upper interconnection structure includes bit lines connected to the channel studs, extending in the third direction, and spaced apart from each other in the second direction, and
the first separation distance is a multiple of pitches of the bit lines.

19. A data storage system, comprising:
a semiconductor storage device including
a first semiconductor structure including a substrate and circuit elements on the substrate,
a second semiconductor structure including
gate electrodes including memory gate electrodes and selection gate electrodes stacked in a first direction, and
channel structures penetrating through the gate electrodes; and
an input/output pad electrically connected to the circuit elements; and
a controller electrically connected to the semiconductor storage device through the input/output pad and configured to control the semiconductor storage device,
the first semiconductor structure further including
a lower interconnection structure electrically connected to the circuit elements; and
a lower bonding structure connected to the lower interconnection structure, and
the second semiconductor structure including
an upper interconnection structure below the gate electrodes;
an upper bonding structure connected to the upper interconnection structure and bonded to the lower bonding structure;
insulating regions extending in a second direction penetrating through the selection gate electrodes, and spaced apart from each other in a third direction to separate the selection gate electrodes into selection gate electrode regions and dummy regions, the second direction being perpendicular to the first direction, the third direction being perpendicular to the second direction;
address studs spaced apart from each other by a first separation distance in the second direction below at least one dummy region, among the dummy regions; and
channel studs below the channel structures,
the upper interconnection structure connected to the channel studs and spaced apart from the address studs.

20. The data storage system of claim 19,
wherein the address studs are arranged in the second direction only below the dummy regions, and the first separation distance is greater than a pitch of the channel structures.
